(19) United States
(12) Patent Application Publication
(10) Pub. No.: US 2026/0113000 A1
(43) Pub. Date: Apr. 23, 2026

(54) RADIO FREQUENCY CIRCUIT, RADIO FREQUENCY MODULE, AND AMPLIFICATION METHOD

(71) Applicant: Murata Manufacturing Co., Ltd., Nagaokakyo-shi (JP)

(72) Inventor: Kouta ARAI, Nagaokakyo-shi (JP)

(21) Appl. No.: 19/368,352

(22) Filed: Oct. 24, 2025

Related U.S. Application Data
(63) Continuation of application No. PCT/JP2024/006937, filed on Feb. 27, 2024.

(30) Foreign Application Priority Data
Apr. 28, 2023 (JP) 2023-074103

(51) Int. Cl. H03F 1/02; H03F 3/24

(52) U.S. Cl. CPC H03F 1/0211; H03F 3/245; H03F 2200/381; H03F 2200/451

(57) ABSTRACT

A radio frequency circuit is provided that includes a power amplifier connected to an antenna and configured to amplify a millimeter-wave signal; a power amplifier connected to an antenna different from the antenna and configured to amplify the millimeter-wave signal; a voltage generation circuit configured to generate multiple discrete voltages based on an input voltage; a first supply modulator configured to selectively output one of the multiple discrete voltages to the power amplifier; and a second supply modulator configured to selectively output one of the multiple discrete voltages to the power amplifier. The first and second supply modulators are configured to select a same voltage from among the multiple discrete voltages in accordance with a first digital control signal.

### CROSS REFERENCE TO RELATED APPLICATIONS

This application is a continuation of International Application No. PCT/JP2024/006937, filed February 27, 2024, which claims priority to Japanese Patent Application No. 2023-074103, filed April 28, 2023, the contents of each of which are hereby incorporated by reference in their entireties.

### TECHNICAL FIELD

The present disclosure relates to a radio frequency (RF) circuit, an RF module, and an amplification method.

### BACKGROUND

In recent years, power-added efficiency (PAE) has been improved by applying an envelope tracking (ET) mode to a power amplifier (PA) circuit. For example, U.S. Patent No. 8,8299,93 discloses a tracker circuit for digital envelope tracking (D-ET).

However, there is growing demand for a compact RF circuit that improves power-added efficiency (PAE) using multiple power amplifiers (PAs) capable of amplifying millimeter-wave signals.

### SUMMARY OF THE INVENTION

Accordingly, the exemplary aspects of the present disclosure provide a compact RF circuit and an RF module that improves improving power-added efficiency (PAE) using multiple power amplifiers configured to amplify millimeter-wave signals, and an amplification method that contributes to the miniaturization of the RF circuit and the RF module.

According to an exemplary aspect, an RF circuit is provided that includes a first power amplifier connected to a first antenna and configured to amplify a millimeter-wave signal; a second power amplifier connected to a second antenna different from the first antenna and configured to amplify the millimeter-wave signal; a voltage generation circuit configured to generate multiple discrete voltages based on an input voltage; a first supply modulator configured to selectively output one of the multiple discrete voltages to the first power amplifier; and a second supply modulator configured to selectively output one of the multiple discrete voltages to the second power amplifier. Moreover, the first supply modulator and the second supply modulator are configured to select a same voltage from among the multiple discrete voltages.

In another exemplary aspect, an RF module is provided that includes a module substrate; and a first integrated circuit and a second integrated circuit arranged on the module substrate. In this aspect, the first integrated circuit includes a first external connection terminal and a second external connection terminal; a third external connection terminal configured to receive a first digital control signal; a first switch section including at least one switch included in a voltage generation circuit that is configured to generate multiple discrete voltages based on an input voltage; a second switch section including at least one switch included in a first supply modulator configured to select one voltage from among the multiple discrete voltages and output the selected voltage to the first external connection terminal; a third switch section including at least one switch included in a second supply modulator that is configured to select a same voltage from among the multiple discrete voltages and output the same selected voltage to the second external connection terminal; and a digital control section configured to control the second switch section and the third switch section in accordance with the first digital control signal. Moreover, the second integrated circuit includes a fourth external connection terminal connected to the first external connection terminal; a fifth external connection terminal connected to the second external connection terminal; a first power amplifier connected to a first antenna and configured to amplify a millimeter-wave signal using a voltage received from the first integrated circuit via the fourth external connection terminal; and a second power amplifier connected to a second antenna different from the first antenna and configured to amplify the millimeter-wave signal using a voltage received from the first integrated circuit via the fifth external connection terminal.

In another exemplary aspect, an amplification method is provided that includes generating multiple discrete voltages based on an input voltage; generating a digital control signal based on an envelope signal of a millimeter-wave signal; selecting one of the multiple discrete voltages in accordance with the digital control signal; supplying the selected voltage to a first power amplifier; amplifying the millimeter-wave signal; outputting the amplified signal to the first antenna; selecting a same voltage from among the multiple discrete voltages in accordance with the digital control signal; supplying the same selected voltage to a second power amplifier; amplifying the millimeter-wave signal; and outputting the amplified signal to a second antenna.

According to the exemplary aspects of the present disclosure power-added efficiency (PAE) is improved using multiple power amplifiers configured to amplify millimeter-wave signals, thereby contributing to the miniaturization of RF circuits.

### BRIEF DESCRIPTION OF DRAWINGS

FIG. 1A is a graph illustrating an example of changes of a power supply voltage in APT (Average Power Tracking) mode.

FIG. 1B is a graph illustrating an example of changes of the power supply voltage in A-ET (Analog Envelope Tracking) mode.

FIG. 1C is a graph illustrating an example of changes of the power supply voltage in D-ET mode.

FIG. 2 is a circuit configuration diagram of a communication device according to a first exemplary embodiment.

FIG. 3 is a circuit configuration diagram of a tracker circuit according to the first exemplary embodiment.

FIG. 4 is a plan view of an RF module according to the first exemplary embodiment.

FIG. 5 is a cross-sectional view of the RF module according to first exemplary embodiment.

FIG. 6 is a flowchart illustrating an amplification method according to the first exemplary embodiment.

FIG. 7A is a circuit configuration diagram of a first voltage adjustment circuit according to a second exemplary embodiment.

FIG. 7B is a circuit configuration diagram of a second voltage adjustment circuit according to the second exemplary embodiment.

FIG. 8 is a plan view of an RF module according to a third exemplary embodiment.

FIG. 9 is a plan view of the RF module according to the third exemplary embodiment.

FIG. 10 is a cross-sectional view of the RF module according to the third exemplary embodiment.

### DETAILED DESCRIPTION OF EMBODIMENTS

Hereinafter, exemplary embodiments of the present disclosure will be described in detail using the drawings. It is noted that the embodiments described hereinafter are all illustrative of comprehensive or specific examples. The numerical values, shapes, materials, components, and component arrangement and connection forms discussed in the following embodiments are merely examples and are not intended to limit the exemplary aspects of the present disclosure.

It is also noted that each of the drawings is a schematic diagram that has been appropriately emphasized, omitted, or adjusted in scale to illustrate the exemplary aspects of the present disclosure. Therefore, the drawings are not necessarily depicted with strict accuracy and may differ from the actual shapes, positional relationships, and proportions. In each of the drawings, the same reference numerals are assigned to substantially identical configurations, and overlapping descriptions may be omitted or simplified.

In each of the following drawings, the x-axis and the y-axis are axes orthogonal to each other on a plane parallel to the main surface of a module substrate. Specifically, in the case where the module substrate has a rectangular shape in a plan view, the x-axis is parallel to a first side of the module substrate, and the y-axis is parallel to a second side, which is orthogonal to the first side of the module substrate. Additionally, the z-axis is an axis perpendicular to the main surface of the module substrate, the positive direction of which indicates an upward direction and the negative direction of which indicates a downward direction.

In the following description, the term "connected" refers not only to direct connections by connection terminals and/or wiring conductors but also to cases where electrical connections are made with other circuit elements interposed therebetween. Moreover, the term "directly connected" refers to direct connections by connection terminals and/or wiring conductors without having other circuit elements interposed therebetween. According to an exemplary aspect, the phrase "C is connected between A and B" indicates that one end of C is connected to A and the other end of C is connected to B, meaning that C is arranged in series in the path connecting A and B. Moreover, the phrase "the path connecting A and B" refers to a path composed of a conductor electrically connecting A to B.

The term "terminal" refers to the point at which a conductor within an element ends. Note that, when the impedance of a conductor between elements is sufficiently low, a terminal is interpreted not only as a single point but also as any point on the conductor between the elements or as the entire conductor.

According to an exemplary aspect, the phrase "the component is arranged on or in the substrate" includes both the arrangement of the component on the main surface of the substrate and the arrangement of the component within the substrate. The phrase "the component is arranged on the main surface of the substrate" includes not only the arrangement of the component in contact with the main surface of the substrate but also the arrangement of the component above the main surface without direct contact with the main surface (for example, when the component is laminated or stacked on another component arranged in contact with the main surface). Additionally, the phrase "the component is arranged on the main surface of the substrate" can include the arrangement of the component in a recess formed in the main surface. The phrase "the component is arranged within the substrate" includes not only the encapsulation of the component within the module substrate but also cases where the entire component is arranged between two main surfaces of the substrate, with a portion of the component not covered by the substrate, as well as cases where only a portion of the component is arranged within the substrate.

According to an exemplary aspect, the phrase "B is closer to A than C" indicates that the distance between A and B is shorter than the distance between A and C". Here, "the distance between A and B" refers to the shortest distance between A and B. That is, "the distance between A and B" indicates the length of the shortest line segment among multiple line segments connecting any point on the surface of A and any point on the surface of B.

Additionally, terms indicating the relationship between elements, such as "parallel" and "vertical", terms indicating the shape of elements, such as "rectangular shape", and numerical ranges do not solely represent strict meanings but also encompass substantially equivalent ranges, including differences of a few percent, for example, as would be appreciated to one skilled in the art.

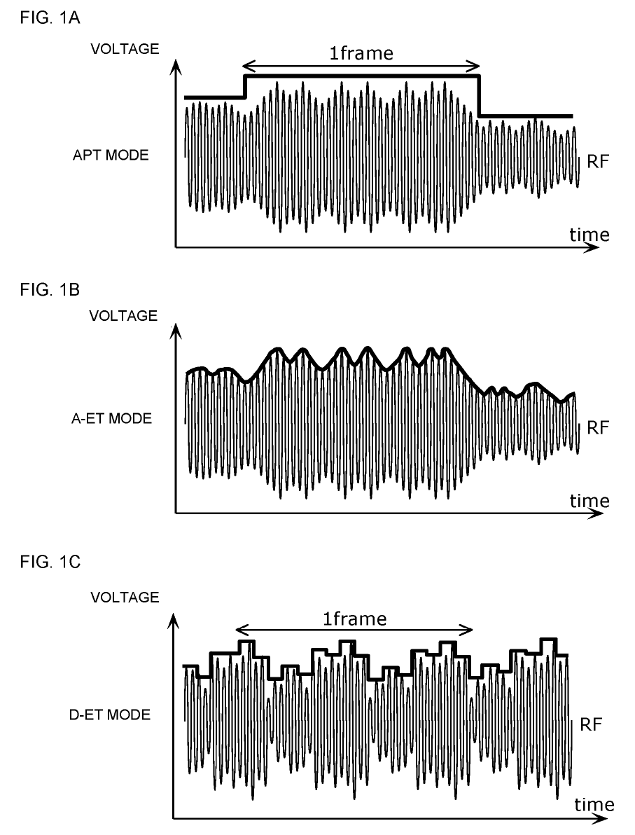

Here, prior to the description of the embodiments, tracking modes, which are techniques for efficiently amplifying RF signals, will be described. In the tracking modes, a power supply voltage that has been dynamically adjusted over time based on an RF signal is supplied to a power amplifier. There are several types of tracking modes including APT mode, A-ET mode, and D-ET mode will be described with reference to FIGS. 1A to 1C. In FIGS. 1A to 1C, the horizontal axis represents time and the vertical axis represents voltage. Additionally, a thick solid line represents a power supply voltage, and a thin solid line (e.g., a waveform) represents a modulated signal.

FIG. 1A is a graph illustrating an example of changes of the power supply voltage in APT mode. APT mode is a mode in which the power supply voltage is varied to multiple discrete voltage levels in units of frames based on the average power.

According to an exemplary aspect, a frame refers to a unit forming an RF signal (e.g., modulated signal). For example, in 5GNR (5th Generation New Radio) and LTE (Long Term Evolution), a frame includes ten subframes, each subframe includes multiple slots, and each slot consists of multiple symbols. The subframe length is 1 millisecond (ms), and the frame length is 10 ms.

It is noted that according to an exemplary aspect, a mode in which the voltage level is varied in units of one frame or larger based on the average power is referred to as APT mode, and is distinguished from a mode in which the voltage level is varied in units smaller than one frame (e.g., subframes, slots, or symbols).

FIG. 1B is a graph illustrating an example of changes of the power supply voltage in A-ET mode. A-ET mode is a mode in which the power supply voltage is continuously varied based on an envelope signal. In A-ET mode, the power supply voltage can track the envelope of a modulated signal.

An envelope signal is a signal that represents the envelope of a modulated signal. The envelope value is represented, for example, by the square root of (I² + Q²), where (I, Q) represents a constellation point. A constellation point is a point that represents a digitally modulated signal on a constellation diagram. (I, Q) is determined, for example, based on information transmitted by a BBIC (Baseband Integrated Circuit).

FIG. 1C is a graph illustrating an example of changes of the power supply voltage in D-ET mode. D-ET mode is a mode in which the power supply voltage is varied to multiple discrete voltage levels within a single frame based on an envelope signal. In D-ET mode, the power supply voltage can track the envelope of a modulated signal. In D-ET, the power supply voltage varies at shorter time intervals than in APT.

### (FIRST EXEMPLARY EMBODIMENT)

A first exemplary embodiment will be described below. A communication device 5 according to the present embodiment can be used for providing wireless connectivity. For example, the communication device 5 can be implemented in user terminals (UE: User Equipment) in a cellular network (also referred to as a mobile network), such as mobile phones, smartphones, tablet computers, wearable devices, and the like. In another example, by implementing the communication device 5, wireless connectivity can be provided to IoT (Internet of Things) sensor devices, medical/healthcare devices, vehicles, unmanned aerial vehicles (UAVs) (so-called drones), and automated guided vehicles (AGVs). In yet another example, by implementing the communication device 5, wireless connectivity can be provided via a wireless access point or a wireless hotspot.

The communication device 5 is configured to transmit millimeter-wave signals. A millimeter-wave signal is a signal in a frequency band within the range of 30 GHz to 300 GHz. In the communication device 5, multiple antennas are used for transmitting millimeter-wave signals in order to realize beamforming, beam steering, or the like.

### [1.1 Circuit Configuration of Communication Device 5]

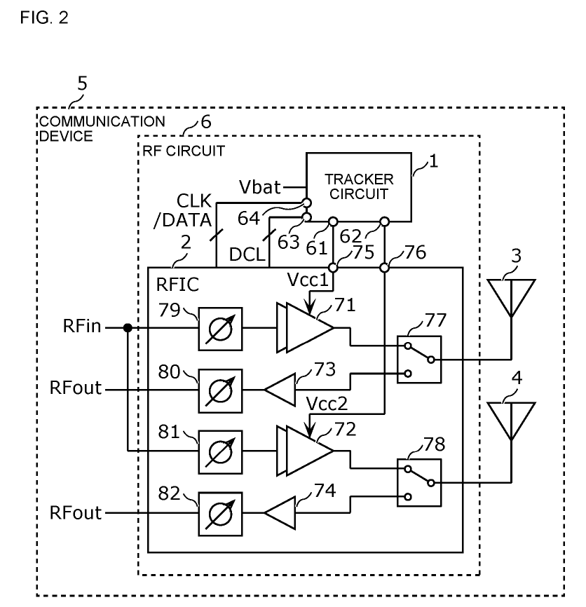

The circuit configuration of the communication device 5 according to the present embodiment will be described with reference to FIG. 2. FIG. 2 is a circuit configuration diagram of the communication device 5 according to the present embodiment.

Note that FIG. 2 illustrates an exemplary circuit configuration, and the communication device 5 may be implemented using any of a wide variety of circuit implementations and circuit technologies. Therefore, the following description of the communication device 5 is not to be interpreted in a limiting sense.

The communication device 5 according to the present embodiment includes an RF circuit 6, which includes a tracker circuit 1 and an RFIC (Radio Frequency Integrated Circuit) 2, and antennas 3 and 4. Note that the communication device 5 may be omitted from the antennas 3 and/or 4 in an alternative aspect.

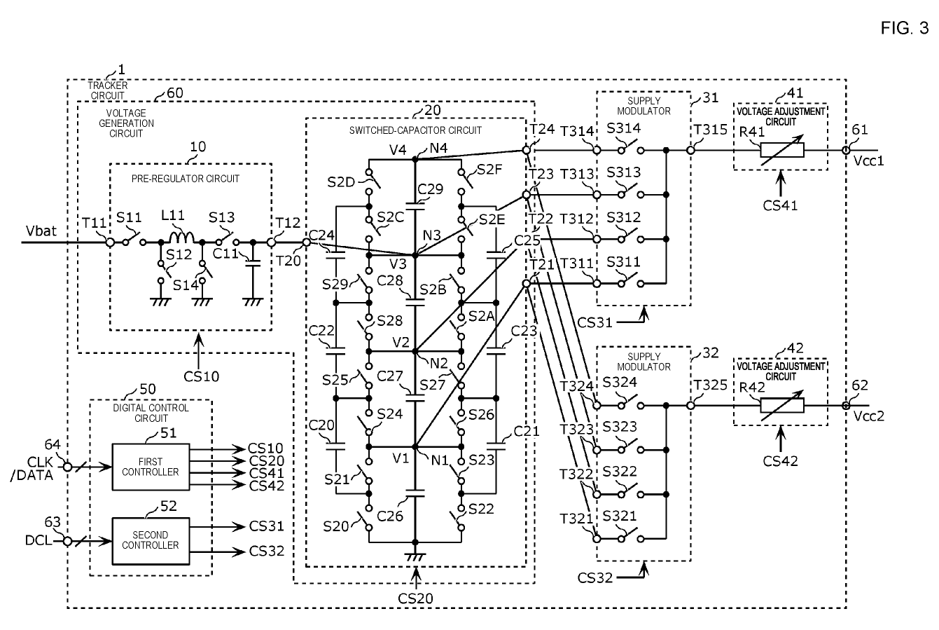

The tracker circuit 1 can simultaneously supply power supply voltages (Vcc1 and Vcc2) to power amplifiers 71 and 72 included in the RFIC 2. The power supply voltages (Vcc1 and Vcc2) are selected from among multiple discrete voltages based on the envelope signal of a millimeter-wave signal amplified by the power amplifiers 71 and 72. The circuit configuration of the tracker circuit 1 will be described later using FIG. 3.

The RFIC 2 can amplify a millimeter-wave signal (RFin), which is an input transmission signal in the millimeter waveband, and output it to the antennas 3 and 4. The RFIC 2 may further amplify a millimeter-wave signal (RFout), which is an input reception signal in the millimeter-wave band from the antennas 3 and 4, and output it. Furthermore, the RFIC 2 can generate a first digital control signal and a second digital control signal for controlling the tracker circuit 1. The circuit configuration of the RFIC 2 will be described later.

The antennas 3 and 4 are examples of a first antenna and a second antenna that are different from each other, and can transmit millimeter-wave signals supplied from the RFIC 2 to the outside. Additionally, the antennas 3 and 4 may also supply millimeter-wave signals received from the outside to the RFIC 2. Note that the communication device 5 may include one or more additional antennas in addition to the antennas 3 and 4. Millimeter-wave signals carrying the same data in the same frequency band are transmitted from the antennas 3 and 4. In this case, the phases and/or polarization directions of the two millimeter-wave signals transmitted from the antennas 3 and 4 may differ.

### [1.2 Circuit Configuration of RFIC 2]

Next, the circuit configuration of the RFIC 2 included in the communication device 5 will be described with reference to FIG. 2. The RFIC 2 includes power amplifiers 71 and 72, low-noise amplifiers 73 and 74, external connection terminals 75 and 76, switch circuits 77 and 78, and phase shifting circuits 79 to 82.

The power amplifier 71 is an example of a first power amplifier and is connected to the antenna 3. Specifically, the input end of the power amplifier 71 is connected to the phase shifting circuit 79, and the output end of the power amplifier 71 is connected to the antenna 3 with the switch circuit 77 interposed therebetween. The power amplifier 71 is further connected to the tracker circuit 1 with the external connection terminal 75 interposed therebetween. The power amplifier 71 is configured to amplify a transmission signal in the millimeter waveband, supplied via the phase shifting circuit 79, by using the power supply voltage (Vcc1) supplied from the tracker circuit 1.

The power amplifier 72 is an example of a second power amplifier and is connected to the antenna 4. Specifically, the input end of the power amplifier 72 is connected to the phase shifting circuit 81, and the output end of the power amplifier 72 is connected to the antenna 4 with the switch circuit 78 interposed therebetween. The power amplifier 72 is further connected to the tracker circuit 1 with the external connection terminal 76 interposed therebetween. The power amplifier 72 is configured to amplify a transmission signal in the millimeter waveband, supplied via the phase shifting circuit 81, by using the power supply voltage (Vcc2) supplied from the tracker circuit 1.

The low-noise amplifier 73 is connected to the antenna 3. Specifically, the input end of the low-noise amplifier 73 is connected to the antenna 3 with the switch circuit 77 interposed therebetween, and the output end of the low-noise amplifier 73 is connected to the phase shifting circuit 80. The low-noise amplifier 73 is configured to amplify a reception signal in the millimeter waveband, received via the antenna 3. Note that the low-noise amplifier 73 may be omitted from the RFIC 2 in an alternative aspect.

The low-noise amplifier 74 is connected to the antenna 4. Specifically, the input end of the low-noise amplifier 74 is connected to the antenna 4 with the switch circuit 78 interposed therebetween, and the output end of the low-noise amplifier 74 is connected to the phase shifting circuit 82. The low-noise amplifier 74 is configured to amplify a reception signal in the millimeter waveband, received via the antenna 4. Note that the low-noise amplifier 74 may be omitted from the RFIC 2 in an alternative aspect.

The external connection terminals 75 and 76 are examples of a fourth external connection terminal and a fifth external connection terminal, and are voltage input terminals for receiving the power supply voltages (Vcc1 and Vcc2), respectively, from the tracker circuit 1. The external connection terminals 75 and 76 are externally connected to external connection terminals 61 and 62 of the tracker circuit 1, respectively, and are internally connected to the power amplifiers 71 and 72, respectively.

The switch circuit 77 is connected between the antenna 3 and each of the power amplifier 71 and the low-noise amplifier 73. The switch circuit 77 is composed of an SPDT (Single-Pole Double-Throw)-type switch circuit, and is configured to switch the connection of the antenna 3 between the power amplifier 71 and the low-noise amplifier 73.

The switch circuit 78 is connected between the antenna 4 and each of the power amplifier 72 and the low-noise amplifier 74. The switch circuit 78 is configured with an SPDT-type switch circuit, and is further configured to switch the connection of the antenna 4 between the power amplifier 72 and the low-noise amplifier 74.

The phase shifting circuits 79 and 81 are connected to the input ends of the power amplifiers 71 and 72, respectively, and are configured to adjust the phase of the millimeter-wave signal (RFin). The phase shifting circuits 80 and 82 are connected to the output ends of the low-noise amplifiers 73 and 74, respectively, and are configured to adjust the phase of the millimeter-wave signal (RFout). Note that the phase shifting circuits 79 to 82 may be omitted from the RFIC 2 in an alternative aspect.

### [1.3 Circuit Configuration of Tracker Circuit 1]

Next, the circuit configuration of the tracker circuit 1 included in the communication device 5 will be described with reference to FIG. 3. FIG. 3 is a circuit configuration diagram of the tracker circuit 1 according to the present embodiment.

Note that FIG. 3 illustrates an exemplary circuit configuration, and the tracker circuit 1 may be implemented using any of a wide variety of circuit implementations and circuit technologies. Therefore, the following description of the tracker circuit 1 is not to be interpreted in a limiting sense.

The tracker circuit 1 includes a voltage generation circuit 60 including a pre-regulator circuit 10 and a switched-capacitor circuit 20, supply modulators 31 and 32, voltage adjustment circuits 41 and 42, a digital control circuit 50, and external connection terminals 61 to 64. Note that the tracker circuit 1 may be omitted from the pre-regulator circuit 10 in an alternative aspect.

The pre-regulator circuit 10 may also be referred to as a magnetic regulator or a DC (Direct Current)/DC converter. In the present embodiment, the pre-regulator circuit 10 is a single-input, single-output buck-boost converter that can convert an input voltage (Vbat) into an output voltage (adjusted voltage). The pre-regulator circuit 10 is configured to adjust the output voltage based on, for example, a second digital control signal from the RFIC 2. The adjusted voltage is supplied to the switched-capacitor circuit 20. Note that the pre-regulator circuit 10 may also be a buck converter or a boost converter.

The switched-capacitor circuit 20 is configured to generate multiple discrete voltages based on the adjusted voltage supplied from the pre-regulator circuit 10. The generated multiple discrete voltages are supplied to the supply modulators 31 and 32.

The voltage generation circuit 60 includes the pre-regulator circuit 10 and the switched-capacitor circuit 20 and is configured to generate multiple discrete voltages based on the input voltage (Vbat). Note that the voltage generation circuit 60 may be of any circuit configuration, and is not limited to the circuit configuration of FIG. 3, as long as it is configured to generate multiple discrete voltages based on the input voltage (Vbat). For example, the voltage generation circuit 60 may include multiple pre-regulator circuits 10, and may omit the switched-capacitor circuit 20 in an alternative aspect.

The supply modulator 31 is configured to selectively output at least one of the multiple discrete voltages generated by the switched-capacitor circuit 20 to the external connection terminal 61. That is, the supply modulator 31 is configured to select at least one voltage from among the multiple discrete voltages and supplying the selected voltage to the power amplifier 71.

The supply modulator 32 is configured to selectively output at least one of the multiple discrete voltages generated by the switched-capacitor circuit 20 to the external connection terminal 62. That is, the supply modulator 32 is configured to select at least one voltage from among the multiple discrete voltages and supplying the selected voltage to the power amplifier 72.

The voltage adjustment circuit 41 is connected between the supply modulator 31 and the external connection terminal 61. The voltage adjustment circuit 41 is configured to adjust the level of the power supply voltage (Vcc1) supplied to the power amplifier 71. Note that the voltage adjustment circuit 41 may be omitted from the tracker circuit 1 in an alternative aspect.

The voltage adjustment circuit 42 is connected between the supply modulator 32 and the external connection terminal 62. The voltage adjustment circuit 42 is configured to adjust the level of the power supply voltage (Vcc2) supplied to the power amplifier 72. Note that the voltage adjustment circuit 42 may be omitted from the tracker circuit 1 in an alternative aspect.

The external connection terminal 61 is an example of a first external connection terminal, and is a voltage output terminal for supplying the power supply voltage (Vcc1) to the power amplifier 71. The external connection terminal 61 is externally connected to the external connection terminal 75 of the RFIC 2 and is internally connected to the supply modulator 31 with the voltage adjustment circuit 41 interposed therebetween.

The external connection terminal 62 is an example of a second external connection terminal, and is a voltage output terminal for supplying the power supply voltage (Vcc2) to the power amplifier 72. The external connection terminal 62 is externally connected to the external connection terminal 76 of the RFIC 2 and is internally connected to the supply modulator 32 with the voltage adjustment circuit 42 interposed therebetween.

The external connection terminals 63 are an example of a third external connection terminal, and are control input terminals for receiving a first digital control signal from the RFIC 2. According to an exemplary aspect, as the first digital control signal, a digital control level (DCL: Digital Control Line) signal based on a parallel data transmission standard can be used, but the signal is not limited thereto.

The DCL signal includes multiple bit signals generated based on the envelope signal of the millimeter-wave signal (RFin) amplified by the RFIC 2. The multiple bit signals are individually input to the multiple external connection terminals 63. Each of multiple discrete voltages (V1 to V4) generated by the switched-capacitor circuit 20 is represented by a combination of two bit signals. For example, the multiple discrete voltages (V1 to V4) are represented as "00", "01", "10", and "11", respectively. Note that gray code may be used to represent the voltage levels.

The external connection terminals 64 are an example of a sixth external connection terminal, and are control input terminals for receiving a second digital control signal from the RFIC 2. According to an exemplary aspect, as the second digital control signal, a digital control signal based on a serial data transmission standard is used, but the signal is not limited thereto.

In the present embodiment, source-synchronous digital control signals (a clock signal (CLK) and data signal (DATA)) are used as digital control signals based on the serial data transmission standard. Note that clock-embedded digital control signals may be used as digital control signals based on the serial data transmission standard.

The digital control circuit 50 is configured to control the pre-regulator circuit 10, the switched-capacitor circuit 20, the supply modulators 31 and 32, and the voltage adjustment circuits 41 and 42 based on digital control signals from the RFIC 2. Note that the digital control circuit 50 may be omitted from the tracker circuit 1 in an alternative aspect.

Note that the circuit configuration of the tracker circuit 1 is exemplary and is not limited thereto. For example, the tracker circuit 1 may include a pulse shaping network (PSN) connected between the supply modulator 31 and the external connection terminal 61 and/or between the supply modulator 32 and the external connection terminal 62.

### [1.3.1 Circuit Configuration of Pre-Regulator Circuit 10]

Next, the detailed circuit configuration of the pre-regulator circuit 10 included in the tracker circuit 1 will be described with reference to FIG. 3. The pre-regulator circuit 10 includes an input terminal T11, an output terminal T12, switches S11 to S14, a power inductor L11, and a capacitor C11.

The input terminal T11 is a terminal for receiving the input voltage (Vbat). The input terminal T11 is externally connected to, for example, a direct current (DC) power source and is internally connected to the switch S11.

The output terminal T12 is a terminal for supplying an adjusted voltage to the switched-capacitor circuit 20. The output terminal T12 is externally connected to the input terminal T20 of the switched-capacitor circuit 20 and is internally connected to the switch S13.

The power inductor L11 is an inductor used to step-up and step-down the input voltage (Vbat). One end of the power inductor L11 is connected to the switches S11 and S12, and the other end of the power inductor L11 is connected to the switches S13 and S14.

The switch S11 is connected between the input terminal T11 and one end of the power inductor L11. In this connection configuration, the switch S11 is switched between on and off, thereby enabling switching between connection and disconnection of the input terminal T11 and one end of the power inductor L11.

The switch S12 is connected between one end of the power inductor L11 and ground. In this connection configuration, the switch S12 is switched between on and off, thereby enabling switching between connection and disconnection of one end of the power inductor L11 and ground.

The switch S13 is connected between the other end of the power inductor L11 and the output terminal T12. In this connection configuration, the switch S13 is switched between on and off, thereby enabling switching between connection and disconnection of the other end of the power inductor L11 and the output terminal T12.

The switch S14 is connected between the other end of the power inductor L11 and ground. In this connection configuration, the switch S14 is switched between on and off, thereby enabling switching between connection and disconnection of the other end of the power inductor L11 and ground.

The capacitor C11 is connected between the path between the switch S13 and the output terminal T12 and ground. Specifically, one of two electrodes of the capacitor C11 is connected to the switch S13 and the output terminal T12, and the other of the two electrodes of the capacitor C11 is connected to ground.

Note that the configuration of the pre-regulator circuit 10 illustrated in FIG. 3 is merely an example, and the configuration is not limited thereto. For example, some of the switches S11 to S14 may be replaced by diodes. Also, a part or all of the pre-regulator circuit 10 may be omitted from the tracker circuit 1 in an alternative aspect.

### [1.3.2 Circuit Configuration of Switched-Capacitor Circuit 20]

Next, the detailed circuit configuration of the switched-capacitor circuit 20 included in the tracker circuit 1 will be described with reference to FIG. 3.

The switched-capacitor circuit 20 has a ladder-type circuit configuration and is configured to generate multiple discrete voltages (V1 to V4). Specifically, the switched-capacitor circuit 20 includes capacitors C20 to C29, switches S20 to S2F, the input terminal T20, and output terminals T21 to T24. Energy and charge are input from the pre-regulator circuit 10 to a node N3 via the input terminal T20 and extracted from nodes N1 to N4 to the supply modulators 31 and 32 via the output terminals T21 to T24.

The input terminal T20 is a terminal for receiving an adjusted voltage from the pre-regulator circuit 10. The input terminal T20 is externally connected to the pre-regulator circuit 10 and is internally connected to the node N3. Note that the node to which the input terminal T20 is connected is not limited to the node N3. The input terminal T20 may be connected to any of the nodes N1 to N4.

The output terminal T21 is a terminal for supplying the voltage (V1) among the multiple discrete voltages (V1 to V4) to the supply modulators 31 and 32. The output terminal T21 is externally connected to the supply modulators 31 and 32 and is internally connected to the node N1.

The output terminal T22 is a terminal for supplying the voltage (V2) among the multiple discrete voltages (V1 to V4) to the supply modulators 31 and 32. The output terminal T22 is externally connected to the supply modulators 31 and 32 and is internally connected to the node N2.

The output terminal T23 is a terminal for supplying the voltage (V3) among the multiple discrete voltages (V1 to V4) to the supply modulators 31 and 32. The output terminal T23 is externally connected to the supply modulators 31 and 32 and is internally connected to the node N3.

The output terminal T24 is a terminal for supplying the voltage (V4) among the multiple discrete voltages (V1 to V4) to the supply modulators 31 and 32. The output terminal T24 is externally connected to the supply modulators 31 and 32 and is internally connected to the node N4.

The capacitors C20 to C25 are flying capacitors (sometimes referred to as transfer capacitors) and are used to step-up and step-down the adjusted voltage (V3) supplied from the pre-regulator circuit 10. More specifically, the capacitors C20 to C25 transfer charge between the capacitors C20 to C25, the nodes N1 to N4, and ground so that the voltages V1 to V4 satisfying (V4 − V3) : (V3 − V2) : (V2 − V1) : (V1 − VG) = 1 : 1 : 1 : 1 and V4 > V3 > V2 > V1 > VG are maintained at the four nodes N1 to N4, where VG represents the ground potential.

One of two electrodes of the capacitor C20 is connected to one end of the switch S20 and one end of the switch S21. The other of the two electrodes of the capacitor C20 is connected to one end of the switch S24 and one end of the switch S25.

One of two electrodes of the capacitor C21 is connected to one end of the switch S22 and one end of the switch S23. The other of the two electrodes of the capacitor C21 is connected to one end of the switch S26 and one end of the switch S27.

One of two electrodes of the capacitor C22 is connected to one end of the switch S24 and one end of the switch S25. The other of the two electrodes of the capacitor C22 is connected to one end of the switch S28 and one end of the switch S29.

One of two electrodes of the capacitor C23 is connected to one end of the switch S26 and one end of the switch S27. The other of the two electrodes of the capacitor C23 is connected to one end of the switch S2A and one end of the switch S2B.

One of two electrodes of the capacitor C24 is connected to one end of the switch S28 and one end of the switch S29. The other of the two electrodes of the capacitor C24 is connected to one end of the switch S2C and one end of the switch S2D.

One of two electrodes of the capacitor C25 is connected to one end of the switch S2A and one end of the switch S2B. The other of the two electrodes of the capacitor C25 is connected to one end of the switch S2E and one end of the switch S2F.

The capacitors C26 to C29 are smoothing capacitors and are used to hold and smooth the voltages (V1 to V4) at the nodes N1 to N4.

The capacitor C26 is connected between the node N1 and ground. Specifically, one of two electrodes of the capacitor C26 is connected to the node N1. Meanwhile, the other of the two electrodes of the capacitor C26 is connected to ground.

The capacitor C27 is connected between the nodes N1 and N2. Specifically, one of two electrodes of the capacitor C27 is connected to the node N2. Meanwhile, the other of the two electrodes of the capacitor C27 is connected to the node N1.

The capacitor C28 is connected between the nodes N2 and N3. Specifically, one of two electrodes of the capacitor C28 is connected to the node N3. Meanwhile, the other of the two electrodes of the capacitor C28 is connected to the node N2.

The capacitor C29 is connected between the nodes N3 and N4. Specifically, one of two electrodes of the capacitor C29 is connected to the node N4. Meanwhile, the other of the two electrodes of the capacitor C29 is connected to the node N3.

The switch S20 is connected between the capacitor C20 and ground. Specifically, one end of the switch S20 is connected to one of the two electrodes of the capacitor C20. Meanwhile, the other end of the switch S20 is connected to ground.

The switch S21 is connected between the capacitor C20 and the node N1. Specifically, one end of the switch S21 is connected to one of the two electrodes of the capacitor C20. Meanwhile, the other end of the switch S21 is connected to the node N1.

The switch S22 is connected between the capacitor C21 and ground. Specifically, one end of the switch S22 is connected to one of the two electrodes of the capacitor C21. Meanwhile, the other end of the switch S22 is connected to ground.

The switch S23 is connected between the capacitor C21 and the node N1. Specifically, one end of the switch S23 is connected to one of the two electrodes of the capacitor C21. Meanwhile, the other end of the switch S23 is connected to the node N1.

The switch S24 is connected between the capacitors C20 and C22 and the node N1. Specifically, one end of the switch S24 is connected to the other of the two electrodes of the capacitor C20 and to one of the two electrodes of the capacitor C22. Meanwhile, the other end of the switch S24 is connected to the node N1.

The switch S25 is connected between the capacitors C20 and C22 and the node N2. Specifically, one end of the switch S25 is connected to the other of the two electrodes of the capacitor C20 and to one of the two electrodes of the capacitor C22. Meanwhile, the other end of the switch S25 is connected to the node N2.

The switch S26 is connected between the capacitors C21 and C23 and the node N1. Specifically, one end of the switch S26 is connected to the other of the two electrodes of the capacitor C21 and to one of the two electrodes of the capacitor C23. Meanwhile, the other end of the switch S26 is connected to the node N1.

The switch S27 is connected between the capacitors C21 and C23 and the node N2. Specifically, one end of the switch S27 is connected to the other of the two electrodes of the capacitor C21 and to one of the two electrodes of the capacitor C23. Meanwhile, the other end of the switch S27 is connected to the node N2.

The switch S28 is connected between the capacitors C22 and C24 and the node N2. Specifically, one end of the switch S28 is connected to the other of the two electrodes of the capacitor C22 and to one of the two electrodes of the capacitor C24. Meanwhile, the other end of the switch S28 is connected to the node N2.

The switch S29 is connected between the capacitors C22 and C24 and the node N3. Specifically, one end of the switch S29 is connected to the other of the two electrodes of the capacitor C22 and to one of the two electrodes of the capacitor C24. Meanwhile, the other end of the switch S29 is connected to the node N3.

The switch S2A is connected between the capacitors C23 and C25 and the node N2. Specifically, one end of the switch S2A is connected to the other of the two electrodes of the capacitor C23 and to one of the two electrodes of the capacitor C25. Meanwhile, the other end of the switch S2A is connected to the node N2.

The switch S2B is connected between the capacitors C23 and C25 and the node N3. Specifically, one end of the switch S2B is connected to the other of the two electrodes of the capacitor C23 and to one of the two electrodes of the capacitor C25. Meanwhile, the other end of the switch S2B is connected to the node N3.

The switch S2C is connected between the capacitor C24 and the node N3. Specifically, one end of the switch S2C is connected to the other of the two electrodes of the capacitor C24. Meanwhile, the other end of the switch S2C is connected to the node N3.

The switch S2D is connected between the capacitor C24 and the node N4. Specifically, one end of the switch S2D is connected to the other of the two electrodes of the capacitor C24. Meanwhile, the other end of the switch S2D is connected to the node N4.

The switch S2E is connected between the capacitor C25 and the node N3. Specifically, one end of the switch S2E is connected to the other of the two electrodes of the capacitor C25. Meanwhile, the other end of the switch S2E is connected to the node N3.

The switch S2F is connected between the capacitor C25 and the node N4. Specifically, one end of the switch S2F is connected to the other of the two electrodes of the capacitor C25. Meanwhile, the other end of the switch S2F is connected to the node N4.

A first set of switches, including the switches S20, S23, S24, S27, S28, S2B, S2C, and S2F, and a second set of switches, including the switches S21, S22, S25, S26, S29, S2A, S2D, and S2E, are alternately switched on and off based on a control signal CS20 from the digital control circuit 50.

Specifically, in a first phase, the first set of switches is turned on and the second set of switches is turned off. Accordingly, one of the two electrodes of the capacitor C20 is connected to ground. The other of the two electrodes of the capacitor C20, one of the two electrodes of the capacitor C21, and one of the two electrodes of the capacitor C22 are connected to the node N1. The other of the two electrodes of the capacitor C21, the other of the two electrodes of the capacitor C22, one of the two electrodes of the capacitor C23, and one of the two electrodes of the capacitor C24 are connected to the node N2. The other of the two electrodes of the capacitor C23, the other of the two electrodes of the capacitor C24, and one of the two electrodes of the capacitor C25 are connected to the node N3. The other of the two electrodes of the capacitor C25 is connected to the node N4.

In contrast, in a second phase, the first set of switches is turned off and the second set of switches is turned on. Accordingly, one of the two electrodes of the capacitor C21 is connected to ground. One of the two electrodes of the capacitor C20, the other of the two electrodes of the capacitor C21, and one of the two electrodes of the capacitor C23 are connected to the node N1. The other of the two electrodes of the capacitor C20, one of the two electrodes of the capacitor C22, the other of the two electrodes of the capacitor C23, and one of the two electrodes of the capacitor C25 are connected to the node N2. The other of the two electrodes of the capacitor C22, one of the two electrodes of the capacitor C24, and the other of the two electrodes of the capacitor C25 are connected to the node N3. The other of the two electrodes of the capacitor C24 is connected to the node N4.

By repeating the first phase and the second phase as above, the capacitors C20 to C25 can perform charging and discharging in a complementary manner. For example, in one of the first phase and the second phase, charging from the capacitors C20, C22, and C24 to the capacitors C26 to C29 is performed, and in the other of the first phase and the second phase, charging from the capacitors C21, C23, and C25 to the capacitors C26 to C29 is performed. That is, the capacitors C26 to C29 are always charged from any of the capacitors C20 to C25; therefore, even when current flows at high speed from any of the nodes N1 to N4 to the supply modulators 31 and 32, any of the nodes N1 to N4 is replenished with charge at high speed, thereby suppressing potential variations at the nodes N1 to N4.

Through such operations, the switched-capacitor circuit 20 can maintain approximately equal voltages at both ends of each of the capacitors C26 to C29. Specifically, at the four nodes N1 to N4 labeled V1 to V4, the voltages V1 to V4 satisfying (V4 − V3) : (V3 − V2) : (V2 − V1) : (V1 − VG) = 1 : 1 : 1 : 1 are maintained. For example, when the adjusted voltage supplied from the pre-regulator circuit 10 is 3 V, the switched-capacitor circuit 20 can generate (1V, 2V, 3V, and 4V) as the multiple discrete voltages (V1 to V4).

It is noted that (V4 − V3) : (V3 − V2) : (V2 − V1) : (V1 − VG) is not limited to 1 : 1 : 1 : 1, and may be designed to any ratio (e.g., 1 : 2 : 3 : 4 or 4 : 3 : 2 : 1) according to alternative exemplary aspects.

[1.3.3 Circuit Configuration of Supply Modulator 31]

Next, the detailed circuit configuration of the supply modulator 31 included in the tracker circuit 1 will be described with reference to FIG. 3.

The supply modulator 31 includes input terminals T311 to T314, switches S311 to S314, and an output terminal T315.

The input terminals T311 to T314 are terminals for receiving the multiple discrete voltages (V1 to V4) generated by the switched-capacitor circuit 20. The input terminals T311 to T314 are externally connected to the output terminals T21 to T24 of the switched-capacitor circuit 20, respectively, and are internally connected to the switches S311 to S314, respectively.

The output terminal T315 is a terminal for outputting a voltage selected from among the multiple discrete voltages (V1 to V4). The output terminal T315 is externally connected to the voltage adjustment circuit 41 and is internally connected to the switches S311 to S314.

The switch S311 is connected between the input terminal T311 and the output terminal T315. In this connection configuration, the switch S311 is switched between on and off by a control signal CS31 from a second controller 52, thereby enabling switching between connection and disconnection of the input terminal T311 and the output terminal T315.

The switch S312 is connected between the input terminal T312 and the output terminal T315. In this connection configuration, the switch S312 is switched between on and off by the control signal CS31 from the second controller 52, thereby enabling switching between connection and disconnection of the input terminal T312 and the output terminal T315.

The switch S313 is connected between the input terminal T313 and the output terminal T315. In this connection configuration, the switch S313 is switched between on and off by the control signal CS31 from the second controller 52, thereby enabling switching between connection and disconnection of the input terminal T313 and the output terminal T315.

The switch S314 is connected between the input terminal T314 and the output terminal T315. In this connection configuration, the switch S314 is switched between on and off by the control signal CS31 from the second controller 52, thereby enabling switching between connection and disconnection of the input terminal T314 and the output terminal T315.

In the present embodiment, these switches S311 to S314 are controlled to be turned on exclusively. That is, only one of the switches S311 to S314 is closed, while all the remaining ones of the switches S311 to S314 are controlled to be open. This allows the supply modulator 31 to output one voltage selected from among the multiple discrete voltages (V1 to V4) to the external connection terminal 61 via the voltage adjustment circuit 41.

Note that the configuration of the supply modulator 31 illustrated in FIG. 3 is merely an example, and the configuration is not limited thereto. In particular, the switches S311 to S314 may be of any configuration and controlled in any way, as long as they are configured to selectively connect at least one of the four input terminals T311 to T314 to the output terminal T315. For example, two of the switches S311 to S314 may be closed, while the remaining ones of the switches S311 to S314 may be opened.

[1.3.4 Circuit Configuration of Supply Modulator 32]

Next, the detailed circuit configuration of the supply modulator 32 included in the tracker circuit 1 will be described with reference to FIG. 3.

The supply modulator 32 includes input terminals T321 to T324, switches S321 to S324, and an output terminal T325.

The input terminals T321 to T324 are terminals for receiving the multiple discrete voltages (V1 to V4) generated by the switched-capacitor circuit 20. The input terminals T321 to T324 are externally connected to the output terminals T21 to T24 of the switched-capacitor circuit 20, respectively, and are internally connected to the switches S321 to S324, respectively.

The output terminal T325 is a terminal for outputting a voltage selected from among the multiple discrete voltages (V1 to V4). The output terminal T325 is externally connected to the voltage adjustment circuit 42 and is internally connected to the switches S321 to S324.

The switch S321 is connected between the input terminal T321 and the output terminal T325. In this connection configuration, the switch S321 is switched between on and off by a control signal CS32 from the second controller 52, thereby enabling switching between connection and disconnection of the input terminal T321 and the output terminal T325.

The switch S322 is connected between the input terminal T322 and the output terminal T325. In this connection configuration, the switch S322 is switched between on and off by the control signal CS32 from the second controller 52, thereby enabling switching between connection and disconnection of the input terminal T322 and the output terminal T325.

The switch S323 is connected between the input terminal T323 and the output terminal T325. In this connection configuration, the switch S323 is switched between on and off by the control signal CS32 from the second controller 52, thereby enabling switching between connection and disconnection of the input terminal T323 and the output terminal T325.

The switch S324 is connected between the input terminal T324 and the output terminal T325. In this connection configuration, the switch S324 is switched between on and off by the control signal CS32 from the second controller 52, thereby enabling switching between connection and disconnection of the input terminal T324 and the output terminal T325.

In the present embodiment, these switches S321 to S324 are controlled to be turned on exclusively. That is, only one of the switches S321 to S324 is closed, while all the remaining ones of the switches S321 to S324 are controlled to be open. This allows the supply modulator 32 to output one voltage selected from among the multiple discrete voltages (V1 to V4) to the external connection terminal 62 via the voltage adjustment circuit 42.

Note that the configuration of the supply modulator 32 illustrated in FIG. 3 is merely an example, and the configuration is not limited thereto. In particular, the switches S321 to S324 may be of any configuration and controlled in any way, as long as they are configured to selectively connect at least one of the four input terminals T321 to T324 to the output terminal T325. For example, two of the switches S321 to S324 may be closed, while the remaining ones of the switches S321 to S324 may be opened.

[1.3.5 Circuit Configuration of Voltage adjustment circuits 41 and 42]

Next, the circuit configuration of the voltage adjustment circuits 41 and 42 will be described with reference to FIG. 3. The voltage adjustment circuits 41 and 42 include variable resistors R41 and R42, respectively.

The variable resistor R41 is an example of a first variable resistor and is connected between the output terminal T315 of the supply modulator 31 and the external connection terminal 61. The variable resistor R42 is an example of a second variable resistor and is connected between the output terminal T325 of the supply modulator 32 and the external connection terminal 62. The variable resistors R41 and R42 are configured to adjust the output voltages of the supply modulators 31 and 32 in such a manner that the level difference between the power supply voltages Vcc1 and Vcc2, which are supplied from the external connection terminals 61 and 62 to the RFIC 2, is reduced, in accordance with control signals CS41 and CS42. Such adjustment of the output voltages is performed, for example, during calibration. Alternatively, for example, adjustment of the output voltages may be done dynamically in units of frames.

Note that the voltage adjustment circuits 41 and 42 are optional components, and one or both of the voltage adjustment circuits 41 and 42 may be omitted from the tracker circuit 1 in an alternative aspect.

[1.3.6 Circuit Configuration of Digital Control Circuit 50]

Next, the circuit configuration of the digital control circuit 50 included in the tracker circuit 1 will be described with reference to FIG. 3. The digital control circuit 50 includes a first controller 51 and the second controller 52.

The first controller 51 is configured to process a CLK signal and a DATA signal supplied from the RFIC 2 to generate control signals CS10, CS20, CS41, and CS42 for controlling the pre-regulator circuit 10, the switched-capacitor circuit 20, and the voltage adjustment circuits 41 and 42.

The second controller 52 is configured to process a DCL signal supplied from the RFIC 2 in D-ET mode to generate control signals CS31 and 32 for controlling the supply modulators 31 and 32. Since the second controller 52 generates two control signals CS31 and 32 from the same DCL signal, the supply modulators 31 and 32 can be controlled in such a manner that the same voltage is selected from among the multiple discrete voltages (V1 to V4).

[1.4 Implementation Example of RF Circuit 6]

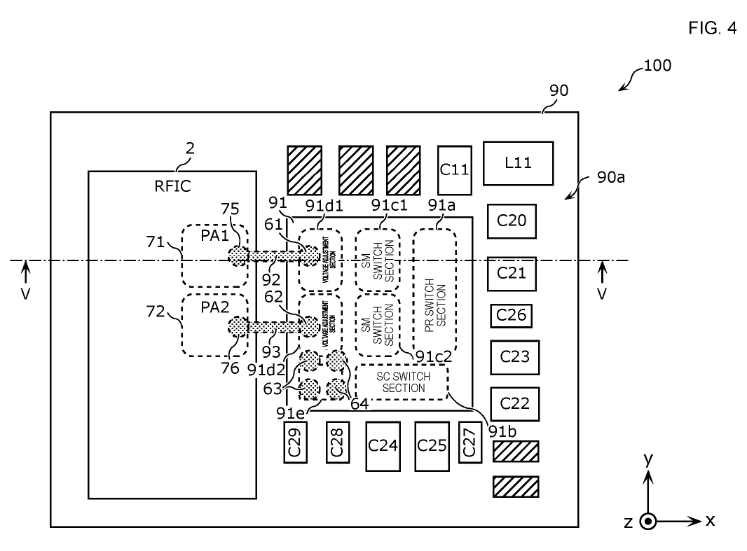

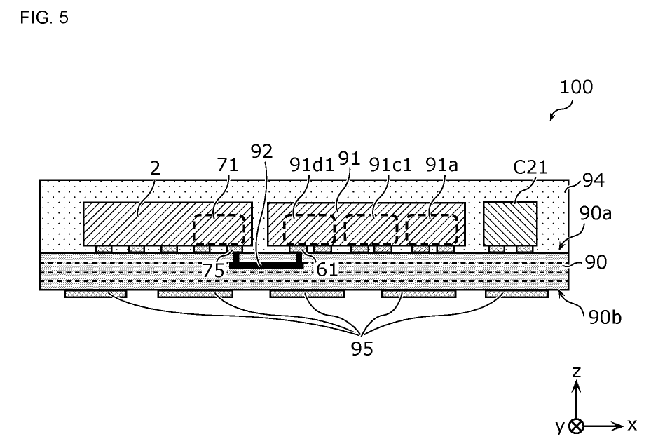

Next, an RF module 100 will be described as an implementation example of the RF circuit 6 with reference to FIGS. 4 and 5. FIG. 4 is a plan view of the RF module 100 according to the present embodiment. FIG. 5 is a cross-sectional view of the RF module 100 according to the present embodiment. The cross-sectional view of the RF module 100 in FIG. 5 is taken along line v–v in FIG. 4.

Note that, in FIG. 4, a resin member 94 covering multiple components on a main surface 90a of a module substrate 90 is omitted. In FIG. 4, the components on the module substrate 90 are attached with labels indicating reference numerals (e.g., "C20") so that the positional relationship among the components can be easily understood. Additionally, functional regions depicted by broken lines within the RFIC 2 and an integrated circuit 91 are attached with labels indicating their functions (e.g., "SC switch section"). However, such labels need not be attached to the actual components. Furthermore, in FIG. 4, the hatched components represent optional components that may be omitted from the present embodiment according to alternative exemplary aspects.

The RF module 100 includes the module substrate 90 on which the RF circuit 6 illustrated in FIG. 2 is implemented. The module substrate 90 has the main surfaces 90a and 90b facing each other. Via conductors, wiring, and ground planes are formed within the module substrate 90 and on the main surface 90a. In FIGS. 4 and 5, only wiring 92 between the external connection terminal 61 and the external connection terminal 75 and wiring 93 between the external connection terminal 62 and the external connection terminal 76 are illustrated.

As the module substrate 90, for example, a low temperature co-fired ceramic (LTCC) substrate or a high temperature co-fired ceramic (HTCC) substrate having a laminated structure of multiple dielectric layers, a component-embedded board, a substrate having a redistribution layer (RDL), or a printed circuit board can be used; however, the module substrate 90 is not limited to these substrates.

The RFIC 2, the integrated circuit 91, the power inductor L11 and the capacitor C11 included in the pre-regulator circuit 10, and the capacitors C20 to C29 included in the switched-capacitor circuit 20 are arranged on the main surface 90a of the module substrate 90. Note that the power inductor L11 may be arranged outside the module substrate 90.

The RFIC 2 is an example of a second integrated circuit, and includes the power amplifiers 71 and 72, the low-noise amplifiers 73 and 74, multiple external connection terminals including the external connection terminals 75 and 76, the switch circuits 77 and 78, and the phase shifting circuits 79 to 82. In FIG. 4, only the portions where the power amplifiers 71 and 72 are implemented (hereinafter simply referred to as the power amplifiers 71 and 72) and the external connection terminals 75 and 76 are illustrated, while other circuits and the like are omitted.

The power amplifiers 71 and 72 are arranged in the vicinity of the integrated circuit 91. Specifically, the power amplifier 71 is arranged in the vicinity of a voltage adjustment section 91d1, in which the voltage adjustment circuit 41 of the RFIC 2 is implemented. Additionally, the power amplifier 72 is arranged in the vicinity of the voltage adjustment section 91d2, in which the voltage adjustment circuit 42 of the RFIC 2 is implemented. Note that the positions of the power amplifiers 71 and 72 within the RFIC 2 can be identified based on the positions of amplification transistors.

The multiple external connection terminals of the RFIC 2 are composed of, for example, copper electrodes or solder electrodes, and are electrically connected to input/output terminals and/or ground terminals, for example, on the main surface 90a of the module substrate 90. Note that, in FIG. 4, the multiple external connection terminals of the RFIC 2 are omitted except for the external connection terminals 75 and 76.

The external connection terminal 75 is an example of a fourth external connection terminal and is electrically connected to the external connection terminal 61 of the integrated circuit 91 with the wiring 92 of the module substrate 90 interposed therebetween. Here, the external connection terminal 75 is closer to the external connection terminal 61 of the integrated circuit 91 than the external connection terminal 76. In an exemplary aspect, the external connection terminal 75 is closest to the external connection terminal 61 of the integrated circuit 91 among the multiple external connection terminals of the RFIC 2. This configuration shortens the wiring length of the wiring 92.

The external connection terminal 76 is an example of a fifth external connection terminal and is electrically connected to the external connection terminal 62 of the integrated circuit 91 with the wiring 93 of the module substrate 90 interposed therebetween. Here, the external connection terminal 76 is closer to the external connection terminal 62 of the integrated circuit 91 than the external connection terminal 75. In an exemplary aspect, the external connection terminal 76 is closest to the external connection terminal 62 of the integrated circuit 91 among the multiple external connection terminals of the RFIC 2. This configuration shortens the wiring length of the wiring 93.

The integrated circuit 91 is an example of a first integrated circuit, and includes a PR switch section 91a, an SC switch section 91b, SM switch sections 91c1 and 91c2, the voltage adjustment sections 91d1 and 91d2, a digital control section 91e, and multiple external connection terminals including the external connection terminals 61 to 64.

The PR switch section 91a is an example of a first switch section and includes the switches S11 to S14 of the pre-regulator circuit 10. The SC switch section 91b is an example of a first switch section and includes the switches S20 to S2F of the switched-capacitor circuit 20.

The SM switch section 91c1 is an example of a second switch section and includes the switches S311 to S314 of the supply modulator 31. The SM switch section 91c1 is closer to the power amplifier 71 than the SM switch section 91c2. Additionally, the power amplifier 71 is closer to the SM switch section 91c1 than the power amplifier 72.

The SM switch section 91c2 is an example of a third switch section and includes the switches S321 to S324 of the supply modulator 32. The SM switch section 91c2 is closer to the power amplifier 72 than the SM switch section 91c1. Additionally, the power amplifier 72 is closer to the SM switch section 91c2 than the power amplifier 71.

The voltage adjustment section 91d1 includes the variable resistor R41 of the voltage adjustment circuit 41. The voltage adjustment section 91d2 includes the variable resistor R42 of the voltage adjustment circuit 42. The digital control section 91e includes the first controller 51 and the second controller 52 of the digital control circuit 50.

The multiple external connection terminals of the integrated circuit 91 are composed of, for example, copper electrodes or solder electrodes and are electrically connected to input/output terminals and/or ground terminals, for example, on the main surface 90a of the module substrate 90. Note that, in FIG. 4, the multiple external connection terminals of the integrated circuit 91 are omitted except for the external connection terminals 61 to 64.

The external connection terminal 61 is an example of a first external connection terminal and is electrically connected to the external connection terminal 75 of the RFIC 2 with the wiring 92 of the module substrate 90 interposed therebetween. Here, the external connection terminal 61 is closer to the external connection terminal 75 of the RFIC 2 than the external connection terminal 62. In an exemplary aspect, the external connection terminal 61 is closest to the external connection terminal 75 of the RFIC 2 among the multiple external connection terminals of the integrated circuit 91. This configuration shortens the wiring length of the wiring 92.

The external connection terminal 62 is an example of a second external connection terminal and is electrically connected to the external connection terminal 76 of the RFIC 2 with the wiring 93 of the module substrate 90 interposed therebetween. Here, the external connection terminal 62 is closer to the external connection terminal 76 of the RFIC 2 than the external connection terminal 61. In an exemplary aspect, the external connection terminal 62 is closest to the external connection terminal 76 of the RFIC 2 among the multiple external connection terminals of the integrated circuit 91. This configuration shortens the wiring length of the wiring 93.

The external connection terminals 63 are an example of a third external connection terminal and receive a first digital control signal. The first digital control signal is supplied to the digital control section 91e and is configured to control the switches within the PR switch section 91a and the SC switch section 91b, as well as the variable resistors within the voltage adjustment sections 91d1 and 91d2.

The external connection terminals 64 are an example of a sixth external connection terminal and receive a second digital control signal. The second digital control signal is supplied to the digital control section 91e and is configured to control the switches within the SM switch sections 91c1 and 91c2.

Note that, in FIG. 4, the PR switch section 91a, the SC switch section 91b, the SM switch sections 91c1 and 91c2, and the voltage adjustment sections 91d1 and 91d2 are included in the single integrated circuit 91, but the configuration is not limited thereto. For example, the PR switch section 91a, the SC switch section 91b, the SM switch sections 91c1 and 91c2, and the voltage adjustment sections 91d1 and 91d2 may be individually included in separate integrated circuits. Alternatively, for example, the PR switch section 91a and the SC switch section 91b may be included in a single integrated circuit, while the SM switch sections 91c1 and 91c2 and the voltage adjustment sections 91d1 and 91d2 may be included in another integrated circuit. Note that the integrated circuits may be manufactured using different process technology nodes.

The integrated circuit 91 may be configured, for example, using CMOS (Complementary Metal Oxide Semiconductor), and specifically may be manufactured by an SOI (Silicon on Insulator) process. Note that the integrated circuit 91 is not limited to CMOS.

Each of the capacitors C20 to C29 is implemented as a chip capacitor, which refers to a surface mount device (SMD) forming a capacitor. It is noted that the implementation of multiple capacitors is not limited to chip capacitors. For example, some or all of the multiple capacitors may be included in an integrated passive device (IPD) or may be included in the integrated circuit 91 according to alternative exemplary aspects.

The wiring 92 electrically connects the external connection terminal 61 of the tracker circuit 1 and the external connection terminal 75 of the RFIC 2, which are formed on the integrated circuit 91. The wiring 92 consists of a wiring pattern arranged on the main surface 90a of the module substrate 90 and/or a via conductor and a wiring pattern arranged within the module substrate 90.

The wiring 93 electrically connects the external connection terminal 62 of the tracker circuit 1 and the external connection terminal 76 of the RFIC 2, which are formed on the integrated circuit 91. The wiring 93 consists of a wiring pattern arranged on the main surface 90a of the module substrate 90 and/or a via conductor and a wiring pattern arranged within the module substrate 90.

The resin member 94 covers the components arranged on the main surface 90a of the module substrate 90. The resin member 94 is composed of, for example, an epoxy resin and can be configured to ensure the reliability of multiple electronic components on the main surface 90a, such as mechanical strength and moisture resistance. It is noted that the resin member 94 may be omitted from the RF module 100 in an alternative aspect.

Multiple external connection terminals 95 are arranged on the main surface 90b of the module substrate 90. The multiple external connection terminals 95 are electrically connected to input/output terminals and/or ground terminals, for example, on a motherboard (not illustrated) arranged in the z-axis negative direction of the RF module 100. Additionally, the multiple external connection terminals 95 are electrically connected to multiple components arranged on the main surface 90a with via conductors, for example, formed within the module substrate 90 interposed therebetween.

According to an exemplary aspect, copper electrodes may be used for the multiple external connection terminals 95, but they are not limited thereto. For example, solder electrodes may be used as the multiple external connection terminals 95 in another exemplary aspect.

Note that the RF module 100 illustrated in FIGS. 4 and 5 is merely an example and is not limited thereto. For example, the surface of the resin member 94 may be covered with a shield electrode layer formed by sputtering, for example. By connecting the shield electrode layer to ground, external noise can be suppressed from entering the components within the RF module 100, and generated by the RF module 100 can be suppressed from interfering with other modules or other devices.

### [1.5 Amplification Method]

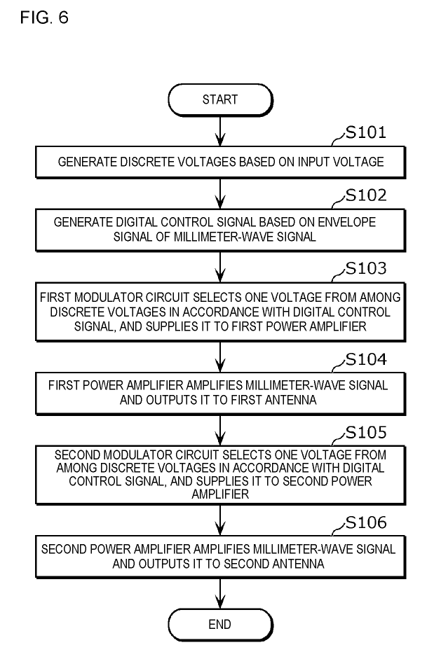

Next, an amplification method according to the present embodiment will be described with reference to FIG. 6. FIG. 6 is a flowchart illustrating the amplification method according to the present embodiment.

First, the voltage generation circuit 60 generates multiple discrete voltages (V1 to V4) based on the input voltage (Vbat) (S101). The RFIC 2 generates a first digital control signal based on the envelope signal of a millimeter-wave signal (S102). The supply modulator 31 selects one voltage from among the multiple discrete voltages (V1 to V4) in accordance with the first digital control signal generated in step S102, and supplies the selected voltage to the power amplifier 71 (S103). The power amplifier 71 amplifies the millimeter-wave signal using the voltage supplied from the supply modulator 31, and outputs the amplified signal to the antenna 3 (S104). The supply modulator 32 selects the same voltage as that in step S103 from among the multiple discrete voltages (V1 to V4) in accordance with the first digital control signal generated in step S102, and supplies the selected voltage to the power amplifier 72 (S105). The power amplifier 72 amplifies the millimeter-wave signal, and outputs the amplified signal to the antenna 4 (S106).

### [1.6 Technical Effects]

As described above, the RF circuit 6 according to the present embodiment includes: the power amplifier 71 connected to the antenna 3 and configured to amplify a millimeter-wave signal; the power amplifier 72 connected to the antenna 4 different from the antenna 3 and configured to amplify the millimeter-wave signal; the voltage generation circuit 60 configured to generate multiple discrete voltages based on an input voltage; the supply modulator 31 configured to selectively output one of the multiple discrete voltages to the power amplifier 71; the supply modulator 32 configured to selectively output one of the multiple discrete voltages to the power amplifier 72, wherein the supply modulator 31 and the supply modulator 32 are configured to select the same voltage from among the multiple discrete voltages in accordance with a first digital control signal.

Accordingly, one voltage selected from among the multiple discrete voltages in accordance with the first digital control signal is supplied to the power amplifiers 71 and 72, which are connected to the different antennas 3 and 4, respectively. Therefore, for example, in the communication device 5 in which millimeter-wave signals carrying the same data are simultaneously transmitted from the two antennas 3 and 4 for beamforming, power-added efficiency can be improved using the two power amplifiers 71 and 72. Additionally, the voltage generation circuit 60 can be shared by the two power amplifiers 71 and 72, thereby reducing the circuit scale of the RF circuit 6 and contributing to the miniaturization of the communication device 5.

Additionally, for example, in the RF circuit 6 according to the present embodiment, the first digital control signal may be a DCL signal based on a parallel data transmission standard.

Accordingly, the switching control of the supply modulators 31 and 32 can be accelerated, and, when D-ET mode is applied to the power amplifiers 71 and 72, the responsiveness to the envelope signals of the power supply voltages (Vcc1 and Vcc2) supplied to the power amplifiers 71 and 72 can be improved.

For example, in the RF circuit 6 according to the present embodiment, the voltage generation circuit 60 may be configured to generate multiple discrete voltages in accordance with a second digital control signal based on a serial data transmission standard.

Accordingly, existing digital control signals can be utilized to control the voltage generation circuit 60 as would be appreciated to one skilled in the art.

Moreover, for example, the RF circuit 6 according to the present embodiment may further include the voltage adjustment circuit 41 connected between the supply modulator 31 and the power amplifier 71 and configured to adjust the voltage output from the supply modulator 31.

Accordingly, in an exemplary aspect, when there is a level difference between the power supply voltage Vcc1 supplied to the power amplifier 71 and the power supply voltage Vcc2 supplied to the power amplifier 72, the level of the power supply voltage Vcc1 can be adjusted by the voltage adjustment circuit 41, thereby reducing the level difference between the power supply voltages Vcc1 and Vcc2. As a result, the error can be reduced between the two millimeter-wave signals that are respectively amplified by the two power amplifiers 71 and 72.

For example, in the RF circuit 6 according to the present embodiment, the voltage adjustment circuit 41 may include the variable resistor R41.

Accordingly, the voltage adjustment circuit 41 can be realized with a simplified configuration.

Additionally, for example, the RF circuit 6 according to the present embodiment may further include the voltage adjustment circuit 42 connected between the supply modulator 32 and the power amplifier 72 and configured to adjust the voltage output from the supply modulator 32.

Accordingly, in an exemplary aspect, when there is a level difference between the power supply voltage Vcc1 supplied to the power amplifier 71 and the power supply voltage Vcc2 supplied to the power amplifier 72, the level of the power supply voltage Vcc2 can be adjusted by the voltage adjustment circuit 42, thereby reducing the level difference between the power supply voltages Vcc1 and Vcc2. As a result, the error can be reduced between the two millimeter-wave signals that are respectively amplified by the two power amplifiers 71 and 72.

For example, in the RF circuit 6 according to the present embodiment, the voltage adjustment circuit 42 may include the variable resistor R42.

Accordingly, the voltage adjustment circuit 42 can be realized with a simplified configuration.

Furthermore, the RF module 100 according to the present embodiment includes: the module substrate 90; and the integrated circuit 91 and the RFIC 2 arranged on the module substrate 90, wherein: the integrated circuit 91 includes: the external connection terminals 61 and 62; the external connection terminal 63 receiving a first digital control signal; the PR switch section 91a and the SC switch section 91b including at least one switch included in the voltage generation circuit 60 configured to generate multiple discrete voltages based on an input voltage; the SM switch section 91c1 including at least one switch included in the supply modulator 31 configured to select one voltage from among the multiple discrete voltages and output the selected voltage to the external connection terminal 61; the SM switch section 91c2 including at least one switch included in the supply modulator 32 configured to select a same voltage from among the multiple discrete voltages and output the same selected voltage to the external connection terminal 62; and the digital control section 91e configured to control the SM switch sections 91c1 and 91c2 in accordance with the first digital control signal, and the RFIC 2 includes: the external connection terminal 75 connected to the external connection terminal 61; the external connection terminal 76 connected to the external connection terminal 62; the power amplifier 71 configured to amplify a millimeter-wave signal using a voltage received from the integrated circuit 91 via the external connection terminal 75, and connected to the antenna 3; and the power amplifier 72 configured to amplify the millimeter-wave signal using a voltage received from the integrated circuit 91 via the external connection terminal 76, and connected to the antenna 4 different from the antenna 3.

Accordingly, one voltage selected from among the multiple discrete voltages in accordance with the first digital control signal is supplied to the power amplifiers 71 and 72, which are connected to the different antennas 3 and 4, respectively. Therefore, for example, in the communication device 5 in which millimeter-wave signals carrying the same data are simultaneously transmitted from the two antennas 3 and 4 for beamforming, power-added efficiency cab be improved using the two power amplifiers 71 and 72. Additionally, the voltage generation circuit 60 can be shared by the two power amplifiers 71 and 72, thereby miniaturizing the RF module 100.

For example, in the RF module 100 according to the present embodiment, the SM switch section 91c1 may be closer to the power amplifier 71 than the SM switch section 91c2.

Accordingly, the SM switch section 91c1 can be brought closer to the power amplifier 71, and the wiring length between the SM switch section 91c1 and the power amplifier 71 can be shortened. Therefore, degradation of the power supply voltage Vcc1 modulated by the supply modulator 31 can be suppressed, and the power-added efficiency of the power amplifier 71 can be improved.

Additionally, for example, in the RF module 100 according to the present embodiment, the SM switch section 91c2 may be closer to the power amplifier 72 than the SM switch section 91c1.

Accordingly, the SM switch section 91c2 can be brought closer to the power amplifier 72, and the wiring length between the SM switch section 91c2 and the power amplifier 72 can be shortened. Therefore, degradation of the power supply voltage Vcc2 modulated by the supply modulator 32 can be suppressed, and the power-added efficiency of the power amplifier 72 can be improved.

Additionally, for example, in the RF module 100 according to the present embodiment, the power amplifier 71 may be closer to the SM switch section 91c1 than the power amplifier 72.

Accordingly, the power amplifier 71 can be brought closer to the SM switch section 91c1, and the wiring length between the SM switch section 91c1 and the power amplifier 71 can be shortened. Therefore, degradation of the power supply voltage Vcc1 modulated by the supply modulator 31 can be suppressed, and the power-added efficiency of the power amplifier 71 can be improved.

Additionally, for example, in the RF module 100 according to the present embodiment, the power amplifier 72 may be closer to the SM switch section 91c2 than the power amplifier 71.

Accordingly, the power amplifier 72 can be brought closer to the SM switch section 91c2, and the wiring length between the SM switch section 91c2 and the power amplifier 72 can be shortened. Therefore, degradation of the power supply voltage Vcc2 modulated by the supply modulator 32 can be suppressed, and the power-added efficiency of the power amplifier 72 can be improved.

Furthermore, for example, in the RF module 100 according to the present embodiment, the external connection terminal 61 may be closer to the external connection terminal 75 than the external connection terminal 62.

Accordingly, the external connection terminal 61 can be brought closer to the external connection terminal 75, and the wiring length of the wiring 92 between the external connection terminals 61 and 75 can be shortened. Therefore, degradation of the power supply voltage Vcc1 supplied to the power amplifier 71 via the external connection terminals 61 and 75 can be suppressed, and the power-added efficiency of the power amplifier 71 can be improved.

Additionally, for example, in the RF module 100 according to the present embodiment, the external connection terminal 62 may be closer to the external connection terminal 76 than the external connection terminal 61.

Accordingly, the external connection terminal 62 can be brought closer to the external connection terminal 76, and the wiring length of the wiring 93 between the external connection terminals 62 and 76 can be shortened. Therefore, degradation of the power supply voltage Vcc2 supplied to the power amplifier 72 via the external connection terminals 62 and 76 can be suppressed, and the power-added efficiency of the power amplifier 72 can be improved.

Moreover, for example, in the RF module 100 according to the present embodiment, the external connection terminal 75 may be closer to the external connection terminal 61 than the external connection terminal 76.

Accordingly, the external connection terminal 75 can be brought closer to the external connection terminal 61, and the wiring length of the wiring 92 between the external connection terminals 61 and 75 can be shortened. Therefore, degradation of the power supply voltage Vcc1 supplied to the power amplifier 71 via the external connection terminals 61 and 75 can be suppressed, and the power-added efficiency of the power amplifier 71 can be improved.

Additionally, for example, in the RF module 100 according to the present embodiment, the external connection terminal 76 may be closer to the external connection terminal 62 than the external connection terminal 75.

Accordingly, the external connection terminal 76 can be brought closer to the external connection terminal 62, and the wiring length of the wiring 93 between the external connection terminals 62 and 76 can be shortened. Therefore, degradation of the power supply voltage Vcc2 supplied to the power amplifier 72 via the external connection terminals 62 and 76 can be suppressed, and the power-added efficiency of the power amplifier 72 can be improved.

Additionally, the amplification method according to the present embodiment includes: generating multiple discrete voltages based on an input voltage (S101); generating a digital control signal based on an envelope signal of a millimeter-wave signal (S102); the supply modulator 31 selecting one voltage from among the multiple discrete voltages in accordance with the digital control signal and supplying the selected voltage to the power amplifier 71 (S103); the power amplifier 71 amplifying the millimeter-wave signal and outputting the amplified signal to the antenna 3 (S104); the supply modulator 32 selecting the same voltage from among the multiple discrete voltages in accordance with the digital control signal and supplying the selected voltage to the power amplifier 72 (S105); and the power amplifier 72 amplifying the millimeter-wave signal and outputting the amplified signal to the antenna 4 (S106).

Accordingly, one voltage selected from among the multiple discrete voltages in accordance with the digital control signal based on the envelope signal is supplied to the power amplifiers 71 and 72 connected to the different antennas 3 and 4, respectively. Therefore, for example, in the communication device 5 in which millimeter-wave signals carrying the same data are simultaneously transmitted from the two antennas 3 and 4 for beamforming, it is possible to apply D-ET mode to the two power amplifiers 71 and 72 and improve the power-added efficiency of the two power amplifiers 71 and 72.

### SECOND EXEMPLARY EMBODIMENT

A second exemplary embodiment will now be described. In the present embodiment, the configuration of the voltage adjustment circuits is mainly different from that of the first exemplary embodiment. Hereinafter, the present embodiment will be described with reference to the drawings, focusing on differences from the first exemplary embodiment.

The tracker circuit 1 according to the present embodiment differs from the tracker circuit 1 according to the first exemplary embodiment in the point that it includes voltage adjustment circuits 41A and 42A instead of the voltage adjustment circuits 41 and 42. Therefore, the descriptions of circuits other than the voltage adjustment circuits 41A and 42A will be omitted.

[2.1 Circuit Configuration of Voltage adjustment circuits 41A and 42A]

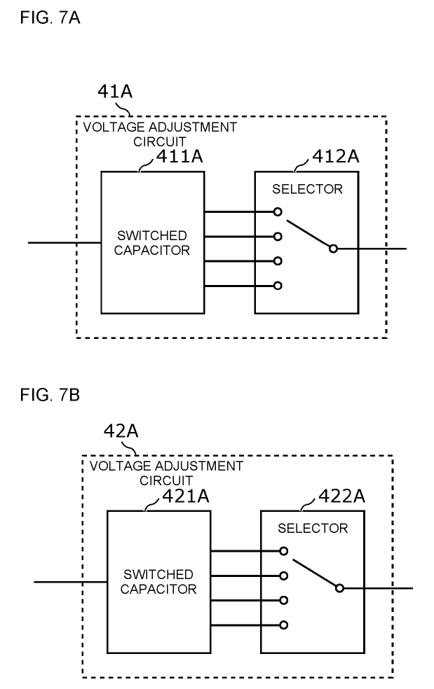

The circuit configuration of the voltage adjustment circuits 41A and 42A will be described with reference to FIGS. 7A and 7B. Note that FIGS. 7A and 7B illustrate an exemplary circuit configuration, and the voltage adjustment circuits 41A and 42A may be implemented using any of a wide variety of circuit implementations and circuit technologies. Therefore, the following description of the voltage adjustment circuits 41A and 42A is not to be interpreted in a limiting sense.

The voltage adjustment circuit 41A includes a switched capacitor 411A and a selector 412A.

The switched capacitor 411A is an example of a first switched capacitor and is configured to generate multiple voltages from a voltage supplied from the supply modulator 31. Because the circuit configuration of the switched capacitor 411A is the same as or similar to that of the switched-capacitor circuit 20, its illustration and description are omitted.

The selector 412A is an example of a first selector and is configured to select one voltage from among the multiple voltages generated by the switched capacitor 411A. The selected voltage is output to the external connection terminal 61. Because the circuit configuration of the selector 412A is the same as or similar to that of the supply modulator 31, its description is omitted. Note that the selector 412A differs from the supply modulator 31, which is controlled in accordance with the first digital control signal, in that the selector 412A is controlled in accordance with the second digital control signal.

The voltage adjustment circuit 42A includes a switched capacitor 421A and a selector 422A.

The switched capacitor 421A is an example of a second switched capacitor and is configured to generate multiple voltages from a voltage supplied from the supply modulator 32. Because the circuit configuration of the switched capacitor 421A is the same as or similar to that of the switched-capacitor circuit 20, its illustration and description are omitted.

The selector 422A is an example of a second selector and is configured to select one voltage from among the multiple voltages generated by the switched capacitor 421A. The selected voltage is output to the external connection terminal 62. Because the circuit configuration of the selector 422A is the same as or similar to that of the supply modulator 32, its description is omitted. Note that the selector 422A differs from the supply modulator 32, which is controlled in accordance with the first digital control signal, in that the selector 422A is controlled in accordance with the second digital control signal.

### [2.2 Technical Effects]

As described above, in the RF circuit 6 according to the present embodiment, the voltage adjustment circuit 41A may include the switched capacitor 411A configured to generate a first plurality of voltages based on a voltage output from the supply modulator 31, and the selector 412A configured to select one first voltage from among the first plurality of voltages generated by the switched capacitor 411A.

Accordingly, the voltage adjustment circuit 41A is configured for not only stepping down but also stepping up the voltage output from the supply modulator 31, thereby improving the flexibility of the voltage adjustment.

As described above, in the tracker circuit 1 according to the present embodiment, the voltage adjustment circuit 42A may include the switched capacitor 421A configured to generate a second plurality of voltages based on a voltage output from the supply modulator 32, and the selector 422A configured to select one second voltage from among the second plurality of voltages generated by the switched capacitor 421A.

Accordingly, the voltage adjustment circuit 42A is configured for capable of not only stepping down but also stepping up the voltage output from the supply modulator 32, thereby improving the flexibility of the voltage adjustment.

### (Third Exemplary Embodiment)

A third exemplary embodiment will now be described. In the present embodiment, the point that the RF circuit 6 is implemented on both sides of the module substrate 90 is mainly different from the first exemplary embodiment. Hereinafter, the present embodiment will be described with reference to the drawings, focusing on differences from the first exemplary embodiment.

Since the circuit configuration of the communication device 5, the tracker circuit 1, and the RFIC 2 is the same as or similar to that of the first exemplary embodiment, their illustrations and descriptions are omitted.

[3.1 Implementation Example of Tracker Circuit 1 and RFIC 2]

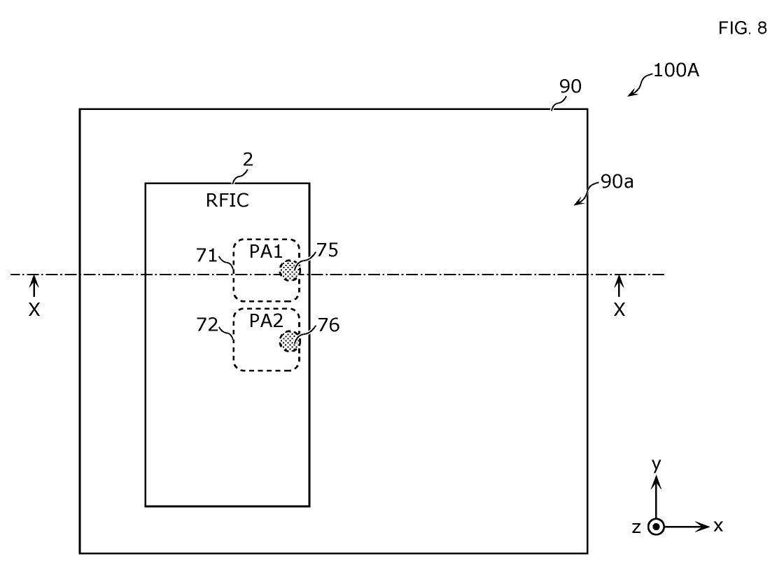

As an implementation example of the RF circuit 6, an RF module 100A according to the present embodiment will be described with reference to FIGS. 8 to 10.

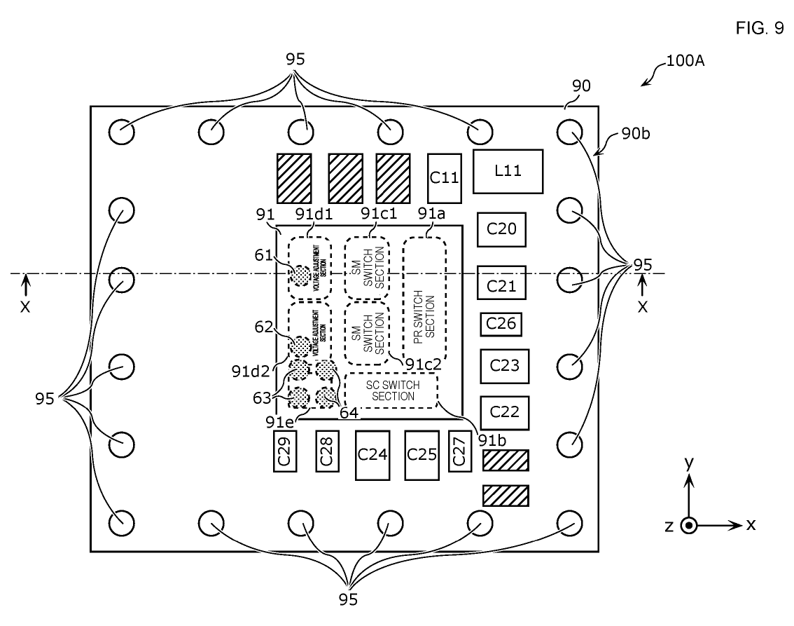

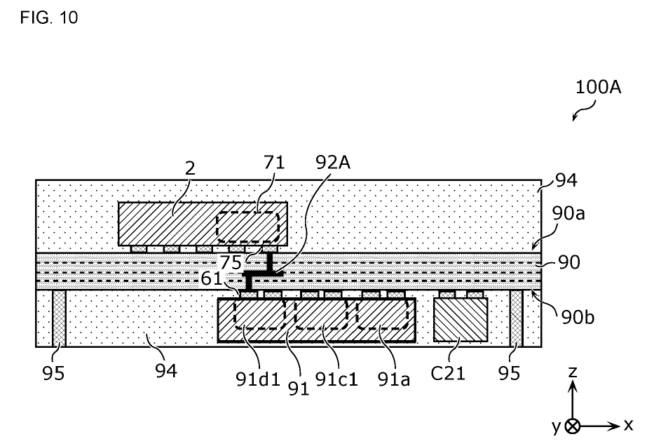

FIG. 8 is a plan view of the RF module 100A according to the present embodiment. FIG. 9 is a plan view of the RF module 100A according to the present embodiment, illustrating the main surface 90b side of the module substrate 90 as viewed from the z-axis positive direction. FIG. 10 is a cross-sectional view of the RF module 100A according to the present embodiment. The cross-section of the RF module 100A in FIG. 10 is taken along line x-x in FIGS. 8 and 9.

In FIGS. 8 and 9, the illustration of the resin member 94, which covers multiple components on the main surfaces 90a and 90b of the module substrate 90, is omitted. In FIGS. 8 and 9, the components on the module substrate 90 are attached with labels indicating reference numerals (e.g., "C20") so that the positional relationship among the components can be easily understood. Additionally, functional regions depicted by broken lines within the RFIC 2 and the integrated circuit 91 are attached with labels indicating their functions (e.g., "SC switch section"). However, such labels need not be attached to the actual components. Furthermore, in FIG. 9, the hatched components represent optional components that may be omitted from the present embodiment according to alternative exemplary aspects.

The RF module 100A includes the module substrate 90 on which the RF circuit 6 illustrated in FIG. 2 is implemented. The module substrate 90 is a double-sided implementation substrate and has main surfaces 90a and 90b facing each other. Via conductors, wiring patterns, and ground planes are formed within the module substrate 90 and on the main surface 90a. Only wiring 92A between the external connection terminal 61 and the external connection terminal 75 is illustrated.

In the present embodiment, the integrated circuit 91, the power inductor L11 and the capacitor C11 included in the pre-regulator circuit 10, and the capacitors C20 to C29 included in the switched-capacitor circuit 20 are arranged on the main surface 90b of the module substrate 90.

The external connection terminal 75 of the RFIC 2 is electrically connected to the external connection terminal 61 of the integrated circuit 91 arranged on the main surface 90b with the wiring 92A of the module substrate 90 interposed therebetween. Here, the external connection terminal 75 is closer to the external connection terminal 61 of the integrated circuit 91 than the external connection terminal 76. This can shorten the wiring length of the wiring 92A.

The external connection terminal 76 of the RFIC 2 is electrically connected to the external connection terminal 62 of the integrated circuit 91 arranged on the main surface 90b with wiring (not illustrated) of the module substrate 90 interposed therebetween. Here, the external connection terminal 76 is closer to the external connection terminal 62 of the integrated circuit 91 than the external connection terminal 75. This can shorten the wiring length between the external connection terminals 76 and 62.

The external connection terminal 61 of the integrated circuit 91 is electrically connected to the external connection terminal 75 of the RFIC 2 with the wiring 92A of the module substrate 90 interposed therebetween. Here, the external connection terminal 61 is closer to the external connection terminal 75 of the RFIC 2 than the external connection terminal 62. This can shorten the wiring length of the wiring 92A.

The external connection terminal 62 of the integrated circuit 91 is electrically connected to the external connection terminal 76 of the RFIC 2 with wiring of the module substrate 90 interposed therebetween. Here, the external connection terminal 62 is closer to the external connection terminal 76 of the RFIC 2 than the external connection terminal 61. This can shorten the wiring length between the external connection terminals 62 and 76.

The voltage adjustment section 91d1 within the integrated circuit 91 at least partially overlaps with the power amplifier 71 within the RFIC 2 in a planar view of the module substrate 90. Similarly, the voltage adjustment section 91d2 within the integrated circuit 91 at least partially overlaps with the power amplifier 72 within the RFIC 2 in a planar view of the module substrate 90.

The wiring 92A electrically connects the external connection terminal 61 of the tracker circuit 1 and the external connection terminal 75 of the RFIC 2, which are formed on the integrated circuit 91. The wiring 92A consists of a wiring pattern arranged on the main surface 90a of the module substrate 90 and/or a via conductor and a wiring pattern arranged within the module substrate 90.

The resin member 94 covers the components arranged on the main surfaces 90a and 90b of the module substrate 90. The resin member 94 is composed of, for example, an epoxy resin and functions to ensure the reliability of multiple electronic components on the main surfaces 90a and 90b, such as mechanical strength and moisture resistance. Note that the resin member 94 may be omitted from the RF module 100A in an alternative aspect.

According to an exemplary aspect, copper post electrodes may be used for the multiple external connection terminals 95, but they are not limited thereto.

### [3.2 Technical Effects]

As described above, in the RF module 100A according to the present embodiment, the RF circuit 6 may be implemented on the main surfaces 90a and 90b, facing each other, of the module substrate 90.

Accordingly, the RF module 100A can be miniaturized.

### (Additional Exemplary Embodiments)

It is noted that the RF circuit, the RF module, and the amplification method according to the present disclosure have been described above based on the embodiments, but the RF circuit, the RF module, and the amplification method are not limited to the embodiments described above. Other embodiments realized by combining arbitrary components in the above-described embodiments, various modifications obtained by applying various changes conceived by those skilled in the art to the above-described embodiments without departing from the spirit of the exemplary embodiment, and various devices incorporating the above-described RF circuit or RF module are also included in the present disclosure.

For example, in the circuit configuration of various circuits according to the above-described embodiments, other circuit elements and wiring may be inserted in the paths that connect the circuit elements and signal lines disclosed in the drawings. For example, a filter and/or an impedance matching circuit may be inserted between the power amplifier 71 and the antenna 3 in alternative exemplary aspects.

Note that the number of multiple discrete voltages generated by the switched-capacitor circuit 20 in the above-described embodiments is exemplary and is not limited to the number indicated in the above-described embodiments. For example, in the above-described embodiments, the switched-capacitor circuit 20 may generate three or fewer discrete voltages, or five or more discrete voltages in alternative exemplary aspects. In this case, the number of steps of the ladder-type circuit configuration of the switched-capacitor circuit 20 may be increased.

Note that, in the above-described embodiments, the communication device 5 may include four power amplifiers and four antennas that are respectively connected to the four power amplifiers. In that case, the tracker circuit 1 may include four supply modulators, and the four supply modulators may respectively supply power supply voltages to the four power amplifiers. Note that the four power amplifiers may be implemented together in a single RFIC, or they may be implemented separately in two RFICs.

In general, the exemplary aspects of the present disclosure can be widely utilized, in communication devices such as mobile phones, as an RF circuit that selectively supplies multiple discrete voltages.

### Reference Signs List

1 tracker circuit

2 RFIC

3 and 4 antennas

5 communication device

6 RF circuit

10 pre-regulator circuit

20 switched-capacitor circuit

31 and 32 supply modulators

41, 41A, 42, and 42A voltage adjustment circuits

50 digital control circuit

51 first controller

52 second controller

60 voltage generation circuit

61, 62, 63, 64, 75, 76, and 95 external connection terminals

71 and 72 power amplifiers

73 and 74 low-noise amplifiers

77 and 78 switch circuits

79, 80, 81, and 82 phase shifting circuits

90 module substrate

90a and 90b main surfaces

91 integrated circuit

91a PR switch section

91b SC switch section

91c1 and 91c2 SM switch sections

91d1 and 91d2 voltage adjustment sections

91e digital control section

92, 92A, and 93 wiring

94 resin member

100 and 100A RF modules

411A and 421A switched capacitors

412A and 422A selectors

1. A radio frequency circuit comprising:
a first power amplifier connected to a first antenna and configured to amplify a millimeter-wave signal;
a second power amplifier connected to a second antenna different from the first antenna and configured to amplify the millimeter-wave signal;
a voltage generation circuit configured to generate a plurality of discrete voltages based on an input voltage;
a first supply modulator configured to selectively output one voltage of the plurality of discrete voltages to the first power amplifier; and
a second supply modulator configured to selectively output one voltage of the plurality of discrete voltages to the second power amplifier,
wherein the first supply modulator and the second supply modulator are configured to select and output the same voltage from among the plurality of discrete voltages to the first and second power amplifiers, respectively.

2. The radio frequency circuit according to claim 1, wherein the first digital control signal is a digital control level signal based on a parallel data transmission standard.

3. The radio frequency circuit according to claim 1, wherein the voltage generation circuit is configured to generate the plurality of discrete voltages in accordance with a second digital control signal that is based on a serial data transmission standard.

4. The radio frequency circuit according to claim 1, further comprising a first voltage adjustment circuit connected between the first supply modulator and the first power amplifier and configured to adjust the voltage output from the first supply modulator.

5. The radio frequency circuit according to claim 4, wherein the first voltage adjustment circuit comprises a first variable resistor.

6. The radio frequency circuit according to claim 4, wherein the first voltage adjustment circuit comprises:
a first switched capacitor configured to generate a first plurality of voltages based on the voltage output from the first supply modulator; and
a first selector configured to select a first voltage from among the first plurality of voltages generated by the first switched capacitor.

7. The radio frequency circuit according to claim 6, further comprising a second voltage adjustment circuit connected between the second supply modulator and the second power amplifier and configured to adjust the voltage output from the second supply modulator.

8. The radio frequency circuit according to claim 7, wherein the second voltage adjustment circuit comprises a second variable resistor.

9. The radio frequency circuit according to claim 7, wherein the second voltage adjustment circuit comprises:
a second switched capacitor configured to generate a second plurality of voltages based on the voltage output from the second supply modulator; and
a second selector configured to select a second voltage from among the second plurality of voltages generated by the second switched capacitor.

10. A radio frequency module comprising:
a module substrate; and
a first integrated circuit on the module substrate, the first integrated circuit including:
a first external connection terminal and a second external connection terminal,
a third external connection terminal configured to receive a first digital control signal,
a first switch section including at least one switch included in a voltage generation circuit that is configured to generate a plurality of discrete voltages based on an input voltage,
a second switch section including at least one switch included in a first supply modulator that is configured to select one voltage from among the plurality of discrete voltages and output the selected voltage to the first external connection terminal,
a third switch section including at least one switch included in a second supply modulator that is configured to select a same voltage that is output to the first external connection terminal and output the same selected voltage to the second external connection terminal, and
a digital control section configured to control the second switch section and the third switch section in accordance with the first digital control signal; and
a second integrated circuit on the module substrate, the second integrated circuit including:
a fourth external connection terminal connected to the first external connection terminal,
a fifth external connection terminal connected to the second external connection terminal,
a first power amplifier connected to a first antenna and configured to amplify a millimeter-wave signal using a voltage received from the first integrated circuit via the fourth external connection terminal, and
a second power amplifier connected to a second antenna different from the first antenna and configured to amplify the millimeter-wave signal using a voltage received from the first integrated circuit via the fifth external connection terminal.

11. The radio frequency module according to claim 10, wherein the second switch section is closer to the first power amplifier than the third switch section.

12. The radio frequency module according to claim 10, wherein the third switch section is closer to the second power amplifier than the second switch section.

13. The radio frequency module according to claim 10, wherein the first power amplifier is closer to the second switch section than the second power amplifier.

14. The radio frequency module according to claim 10, wherein the second power amplifier is closer to the third switch section than the first power amplifier.

15. The radio frequency module according to claim 10, wherein the first external connection terminal is closer to the fourth external connection terminal than the second external connection terminal.

16. The radio frequency module according to claim 10, wherein the second external connection terminal is closer to the fifth external connection terminal than the first external connection terminal.

17. The radio frequency module according to claim 10, wherein the fourth external connection terminal is closer to the first external connection terminal than the fifth external connection terminal.

18. The radio frequency module according to claim 10, wherein the fifth external connection terminal is closer to the second external connection terminal than the fourth external connection terminal.

19. An amplification method comprising:
generating a plurality of discrete voltages based on an input voltage;
generating a digital control signal based on an envelope signal of a millimeter-wave signal;
selecting, by a first supply modulator, one voltage from among the plurality of discrete voltages in accordance with the digital control signal;
supplying, by a first supply modulator, the selected voltage to a first power amplifier;
amplifying, by the first power amplifier, the millimeter-wave signal;
outputting, by the first power amplifier, the amplified signal to the first antenna;
selecting, by a second supply modulator, a same voltage from among the plurality of discrete voltages in accordance with the digital control signal;
supplying, by a second supply modulator, the selected voltage to a second power amplifier;
amplifying, by the second power amplifier, the millimeter-wave signal; and
outputting, by the second power amplifier, the amplified signal to a second antenna.
